(19) United States
(12) Patent Application Publication
(10) Pub. No.: US 2026/0018461 A1
(43) Pub. Date: Jan. 15, 2026

(54) METHOD FOR MANUFACTURING VIA

(71) Applicant: Shanghai Huali Integrated Circuit Corporation, Shanghai (CN)

(72) Inventors: Jinxia Lei, Shanghai (CN); Baojun Zhao, Shanghai (CN)

(73) Assignee: Shanghai Huali Integrated Circuit Corporation, Shanghai (CN)

(21) Appl. No.: 18/809,734

(22) Filed: Aug. 20, 2024

(30) Foreign Application Priority Data
Jul. 11, 2024 (CN) 202410931703.X

(51) Int. Cl. H01L 21/768; H01L 21/02; H01L 21/311; H01L 21/3205; H01L 21/321

(52) U.S. Cl. CPC H01L 21/76883; H01L 21/02274; H01L 21/31116; H01L 21/32051; H01L 21/3212; H01L 21/76802; H01L 21/76831; H01L 21/76843

(57) ABSTRACT

The present disclosure discloses a method for manufacturing a via, including: forming a first dielectric layer on the surface of an underlying structure; performing patterned etching on the first dielectric layer to form a via opening; forming a first metal layer; performing first-time metal CMP to remove the first metal layer on the outer surface of the via opening, where a top surface of the first metal layer in the via opening is located below a top surface of the first dielectric layer; performing second-time dielectric etch back, to selectively etch the first dielectric layer, lower the top surface of the first dielectric layer as being below the top surface of the first metal layer, and form a metal protrusion of a via; and forming a pattern of an upper metal interconnection layer.

### CROSS-REFERENCE TO RELATED APPLICATIONS

This application claims priority to Chinese patent application No. CN202410931703.X, filed on Jul. 11, 2024, the disclosure of which is incorporated herein by reference in its entirety.

### TECHNICAL FIELD

The present disclosure relates to a method for manufacturing a semiconductor integrated circuit, and in particular to a method for manufacturing a via.

### BACKGROUND

Metal tungsten (W) has been widely used as the material of a via, i.e., zeroth layer via (Via0, V0), that connects a front-end-of-line device and back-end-of-line metal due to its low resistivity, and the size of V0 has been scaled down to a width of 26 nm and a height of 31 nm in device processes of some small process nodes. During formation of the via, a W chemical mechanical polishing (CMP) process is required to perform planarization. However, in the W CMP, a polishing slurry may electrochemically react with W to cause metal corrosion, particularly an alkaline polishing slurry, eventually forming a tungsten recess (W recess), which makes it hard to fully connect W and the back-end-of-line interconnection metal. Accordingly, a high resistance may be formed in mild cases, and an open circuit may be directly caused in serious cases, thereby greatly reducing the chip yield.

In an existing improvement method, the CMP is divided into two polishing steps, where excess W is removed in the first polishing step, and in the second polishing step, a dielectric oxide layer through which V0 passes is overpolished using a polishing slurry with a higher selectivity ratio for the oxide, so as to form a W protrusion to compensate for the hazard of the W recess. However, the existing improvement method still has the problems of poor selectivity ratio, uneven polishing rate for different patterns, and scratches on V0 W, which affect the device performance and reduce the chip yield.

FIGS. 1A-1D are schematic diagrams of device structures in steps of an existing method for manufacturing a zeroth layer via.

Step I. A via is defined, including the following.

Referring to FIG. 1A, an underlying structure is provided, a dielectric oxide layer 104 of 500 Å is deposited on the surface of the underlying structure by means of PECVD, and processes such as lithography and etching are sequentially performed to define a V0 pattern, i.e., patterned etching is performed to form a via opening 105.

A process of forming a zeroth metal layer (M0) 102 is completed on the underlying structure.

The material of the zeroth metal layer 102 includes Co.

Referring to FIG. 1A, an underlying oxide layer 101 is used to achieve isolation between patterns of the zeroth metal layer 102. The underlying oxide layer 101 is generally also formed by means of PECVD deposition, and an oxide layer formed by means of PECVD deposition is generally referred to as PEOX.

The underlying structure further includes a semiconductor substrate (not shown) below the underlying dielectric layer 101 and the zeroth metal layer 102. A semiconductor device is formed on the semiconductor substrate. The zeroth metal layer 102 is in contact with a corresponding doped region of the semiconductor device.

Prior to forming the dielectric oxide layer 104, the method further includes forming a thin etch stop layer 103 composed of silicon nitride.

Step II. The via is filled with W, including the following.

Referring to FIG. 1B, an adhesion barrier layer 106 is sequentially grown by means of CVD, where the adhesion barrier layer 106 is formed by stacking a Ti layer and a TiN layer, the thickness of the Ti layer is 25 Å, and the thickness of the TiN layer is 20 Å; and then a W layer 107a of 1600 Å is deposited.

Step III. W CMP is performed on the via, including the following.

Referring to FIG. 1C, excess W and Ti/TiN of the adhesion barrier layer 106 are removed by means of CMP, and overpolishing is performed to ensure that the dielectric oxide layer 104 is fully exposed. The excess W and Ti/TiN of the adhesion barrier layer 106 refer to W and Ti/TiN of the adhesion barrier layer 106 located on the surface of the dielectric oxide layer 104 outside the via opening 105, and W of the via opening 105 located above a top surface of the via opening 105. The top surface of the via opening 105 is flush with a top surface of the dielectric oxide layer 104 outside the via opening 105.

After the CMP is completed, V0, i.e., the zeroth layer via 107, is formed from a remaining W layer 107a. However, referring to FIG. 1C, a top surface of the zeroth layer via 107 is not flush with the top surface of the dielectric oxide layer 104 outside the via opening 105, thus forming a recess.

Step IV. Referring to FIG. 1D, a pattern of back-end-of-line interconnection metal is defined.

Generally, the pattern of back-end-of-line interconnection metal includes patterns of a plurality of metal interconnection layers. FIG. 1D shows a pattern formed by a first metal interconnection layer 110, where the pattern formed by the first metal interconnection layer 110 is, for example, a metal line, i.e., a line of the first metal interconnection layer 110, and the first metal interconnection layer 110 is formed from the material of copper by means of a damascene process. A first interlayer dielectric layer 109 is used to achieve isolation between the patterns of the first metal interconnection layer. Generally, the material of the first interlayer dielectric layer 109 is a low dielectric constant material.

In FIG. 1D, a second etch stop layer 108 is formed at the bottom of the first interlayer dielectric layer 109, where the material of the second etch stop layer 108 includes aluminum oxide (AlO).

Referring to FIG. 1D, due to the presence of the recess as shown in FIG. 1C, after the pattern of the first metal interconnection layer 110 is formed, the pattern of the first metal interconnection layer 110 cannot well contact the corresponding zeroth layer via 107 at the bottom thereof, or even a disconnection structure represented by a mark 111 may be formed. After the pattern of the first metal interconnection layer 110 is disconnected from the corresponding zeroth layer via 107 at the bottom thereof, the conduction therebetween is disabled.

### BRIEF SUMMARY

According to some embodiments in this application, a method for manufacturing a via provided is disclosed in the following steps:
providing an underlying structure, and forming a first dielectric layer on the surface of the underlying structure;
performing patterned etching on the first dielectric layer to form a via opening;
forming a first metal layer that fully fills the via opening and extends to a top surface of the first dielectric layer outside the via opening;
performing first-time metal CMP, where the first-time metal CMP removes the first metal layer on the top surface of the first dielectric layer outside the via opening, and a top surface of the first metal layer in the via opening is located below the top surface of the first dielectric layer;
performing second-time dielectric etch back, where the second-time dielectric etch back selectively etches the first dielectric layer and lower the top surface of the first dielectric layer as being below the top surface of the first metal layer; a via is composed of the first metal layer filling the via opening and includes a metal protrusion formed by the first metal layer above the top surface of the first dielectric layer; the second-time dielectric etch back ensures that the metal protrusion is uniform in a plane and is free of scratch defects; and
forming a pattern of an upper metal interconnection layer, where the metal protrusion ensures that the via is in full contact with the pattern of the upper metal interconnection layer and avoids a high resistance and an open circuit.

In some cases, the first dielectric layer includes an oxide layer.

In some cases, a process for forming the first dielectric layer includes a PECVD deposition process.

In some cases, prior to forming the first metal layer, the method further includes:
forming an adhesion barrier layer, where the adhesion barrier layer is formed on the inner surface of the via opening and extends to the top surface of the first dielectric layer outside the via opening; and the first metal layer fully fills the via opening and extends to the top surface of the adhesion barrier layer outside the via opening.

In some cases, the material of the first metal layer includes W.

The adhesion barrier layer includes a Ti layer and a TiN layer stacked in sequence.

In some cases, the second-time dielectric etch back is implemented by means of a chemical gas etching process.

In some cases, the chemical gas etching process is Certas etching.

In some cases, the second-time dielectric etch back reduces the height of the top surface of the first dielectric layer by 5-10 nm, so that the height of the metal protrusion satisfies a requirement that the via is in full contact with the pattern of the upper metal interconnection layer.

In some cases, an amount of height reduction of the top surface of the first dielectric layer is controlled by controlling a duration of the second-time dielectric etch back.

In some cases, the via is a zeroth layer via; a process of forming a zeroth metal layer is completed on the underlying structure.

The pattern of the upper metal interconnection layer is a pattern of a first metal interconnection layer.

In some cases, the material of the zeroth metal layer includes Co.

In some cases, the material of the first metal interconnection layer includes Cu.

In the prior art, after the via metal layer is formed, i.e., the via opening is filled with the first metal layer, metal CMP is performed once to remove the via metal layer outside the via opening, or dielectric CMP is added to implement the metal protrusion. Unlike the prior art, in the present disclosure, after the first metal layer is formed, the first-time metal CMP is performed to remove the first metal layer on the top surface of the first dielectric layer outside the via opening. In this case, the recess may be formed on the top surface of the first metal layer at the via opening due to the electrochemical reaction corrosion caused by the first-time metal CMP. On that basis, in the present disclosure, instead of continuing the dielectric CMP to remove the recess of the first metal layer, a second-time dielectric etch back process is performed to etch back the first dielectric layer, so as to form the metal protrusion and thereby ensure the elimination of the recess of the first metal layer. With advantages of the second-time dielectric etch back process, such as higher selectivity of the second-time dielectric etch back process for the first dielectric layer, better etching uniformity, and less damage to a surface film, the metal protrusion free of defects and having a specific height may be formed. In particular, the second-time dielectric etch back may be implemented using a chemical gas etching process, such as Certas etching. The Certas etching has an extremely high etching selectivity ratio for oxides and etching uniformity significantly better than that of CMP and causes no damage to a surface film, thereby optimizing the in-plane uniformity of the metal protrusion, eventually ensuring that the via metal layer is in good contact, i.e., full contact, with the pattern of the upper metal interconnection layer, avoiding a high resistance caused by a poor contact or an open circuit caused by contactless disconnection, also ensuring that a via structure is uniform in a plane and free of scratches, thereby improving device performance and increasing a product yield.

The present disclosure is particularly applicable to a relatively low process node. As the process node shrinks, the size of a device decreases, the width and the height of the via, especially the zeroth layer via, decrease, and any defect and damage caused by the CMP during the formation of the via may impose a significant impact on the performance of the device. In the present disclosure, a method of the first-time metal CMP plus the second-time dielectric etch back may be used to improve a structural property of the via at a small process node, avoiding a high contact resistance or an open circuit and thereby improving the device performance.

### BRIEF DESCRIPTION OF THE DRAWINGS

The present disclosure is further described in detail below with reference to the drawings and specific embodiments:

FIGS. 1A-1D are schematic diagrams of device structures in steps of an existing method for manufacturing a zeroth layer via;

FIG. 2 is a flowchart of a method for manufacturing a via according to an embodiment of the present disclosure; and

FIGS. 3A-3E are schematic diagrams of device structures in steps of the method for manufacturing a via according to an embodiment of the present disclosure.

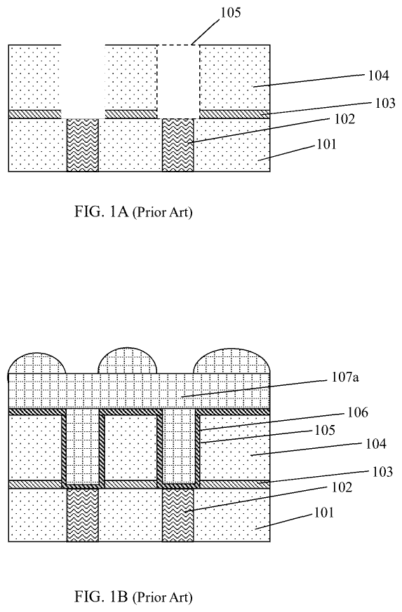

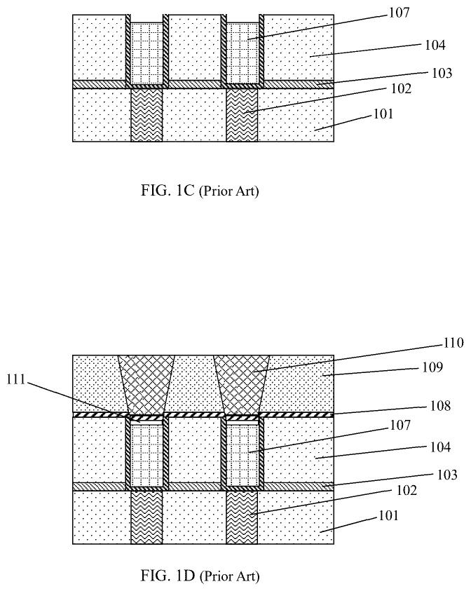

### DETAILED DESCRIPTION OF THE DISCLOSURE

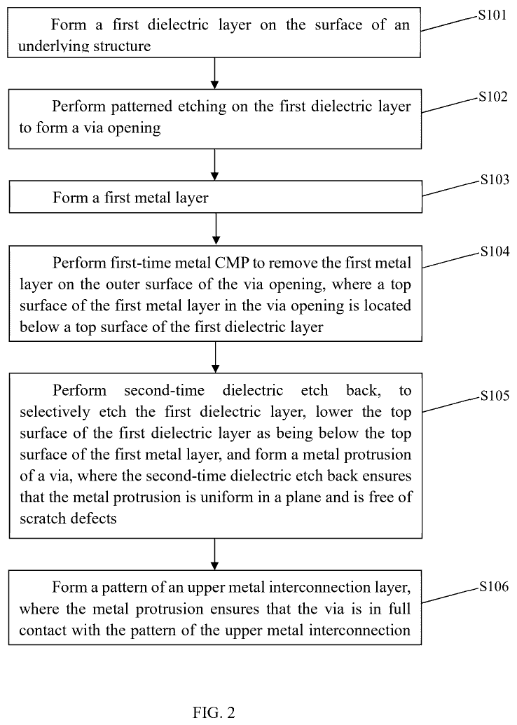

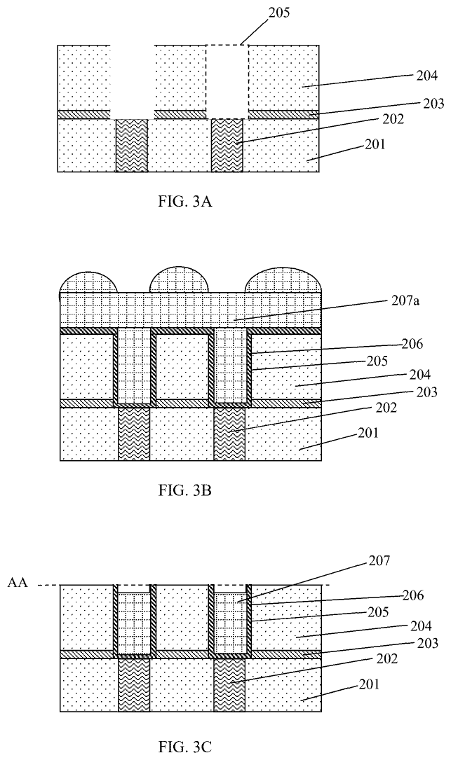

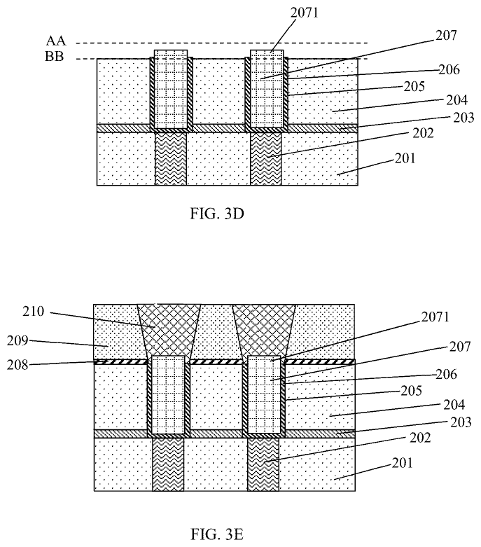

FIG. 2 is a flowchart of a method for manufacturing a via according to an embodiment of the present disclosure. FIGS. 3A-3E are schematic diagrams of device structures in steps of the method for manufacturing a via 207 according to an embodiment of the present disclosure. The method for manufacturing a via according to an embodiment of the present disclosure includes the following steps.

Step S101: Referring to FIG. 3A, an underlying structure is provided, and a first dielectric layer 204 is formed on the surface of the underlying structure.

In the embodiment of the present disclosure, the first dielectric layer 204 includes an oxide layer.

In the embodiment of the present disclosure, a process for forming the first dielectric layer 204 includes a PECVD deposition process.

In the embodiment of the present disclosure, the via 207 is a zeroth layer via; a process of forming a zeroth metal layer 202 is completed on the underlying structure.

The material of the zeroth metal layer 202 includes Co.

Referring to FIG. 3A, an underlying dielectric layer 201 is used to achieve isolation between patterns of the zeroth metal layer 202. The underlying structure further includes a semiconductor substrate (not shown) below the underlying dielectric layer 201 and the zeroth metal layer 202. A semiconductor device is formed on the semiconductor substrate. The zeroth metal layer 202 is in contact with a corresponding doped region of the semiconductor device.

In some embodiments, prior to forming the first dielectric layer 204, the method further includes: forming a thin etch stop layer 203, where the material of the etch stop layer 203 is different from the material of the first dielectric layer 204, for example, the first dielectric layer 204 is an oxide layer and the etch stop layer 203 is a silicon nitride layer.

Step S102: Referring to FIG. 3A, patterned etching is performed on the first dielectric layer 204 to form a via opening 205.

A patterned etching process for the via opening 205 includes: first defining a formation region for the via opening 205 by means of a lithographic process, and then performing etching to form the via opening 205.

In some embodiments, when the etch stop layer 203 is formed at the bottom of the first dielectric layer 204, the etching process for the via opening 205 etches the first dielectric layer 204 using the etch stop layer 203 as an end point, and then the etch stop layer 203 is etched through.

Step S103: Referring to FIG. 3B, a first metal layer 207a that fully fills the via opening 205 and extends to a top surface of the first dielectric layer 204 outside the via opening 205 is formed.

In the embodiment of the present disclosure, prior to forming the first metal layer 207a, the method further includes:

forming an adhesion barrier layer 206, where the adhesion barrier layer 206 is formed on the inner surface of the via opening 205 and extends to the top surface of the first dielectric layer 204 outside the via opening 205; and the first metal layer 207a fully fills the via opening 205 and extends to the top surface of the adhesion barrier layer 206 outside the via opening 205.

In some embodiments, the material of the first metal layer 207a includes W. The adhesion barrier layer 206 includes a Ti layer and a TiN layer stacked in sequence.

Step S104: Referring to FIG. 3C, first-time metal CMP is performed, where the first-time metal CMP removes the first metal layer 207a on the top surface of the first dielectric layer 204 outside the via opening 205, and a top surface of the first metal layer 207a in the via opening 205 is located below the top surface of the first dielectric layer 204. In FIG. 3C, a dashed line AA represents the top surface of the first dielectric layer 204, so that in the via opening 205, a recess is formed at the top of the first metal layer 207a. The recess of the first metal layer 207a is formed because a polishing slurry for the first-time metal CMP may cause an electrochemical reaction with a corrosive effect on metal of the first metal layer 207a, which results in the recess.

Step S105: Referring to FIG. 3D, second-time dielectric etch back is performed, where the second-time dielectric etch back selectively etches the first dielectric layer 204 and lower the top surface of the first dielectric layer 204 as being below the top surface of the first metal layer 207a; a via 207 is composed of the first metal layer 207a filling the via opening 205 and includes a metal protrusion 2071 formed by the first metal layer 207a above the top surface of the first dielectric layer 204; the second-time dielectric etch back ensures that the metal protrusion 2071 is uniform in a plane and is free of scratch defects.

Referring to FIG. 3D, after the second-time dielectric etch back, the top surface of the first dielectric layer 204 is lowered from the dashed line AA to a dashed line BB. As such, the top surface of the first metal layer 207a protrudes from a position indicated by the dashed line BB, thereby forming the metal protrusion 2071.

In the embodiment of the present disclosure, the second-time dielectric etch back is implemented by means of a chemical gas etching process. In some examples, the chemical gas etching process is Certas etching.

In some embodiments, the second-time dielectric etch back reduces the height of the top surface of the first dielectric layer 204 by 5-10 nm, so that the height of the metal protrusion 2071 satisfies a requirement that the via 207 is in full contact with the pattern of the upper metal interconnection layer 210.

In some embodiments, an amount of height reduction of the top surface of the first dielectric layer 204 is controlled by controlling a duration of the second-time dielectric etch back.

Step S106: Referring to FIG. 3E, a pattern of an upper metal interconnection layer 210 is formed, where the metal protrusion 2071 ensures that the via 207 is in full contact with the pattern of the upper metal interconnection layer 210 and avoids a high resistance and an open circuit.

In the embodiment of the present disclosure, since the via 207 is the zeroth layer via, the pattern of the upper metal interconnection layer 210 is a pattern of a first metal interconnection layer.

In some embodiments, the material of the first metal interconnection layer includes Cu.

Referring to FIG. 3E, a first interlayer dielectric layer 209 is used to achieve isolation between the patterns of the first metal interconnection layer. In some embodiments, the material of the first interlayer dielectric layer 209 includes a low dielectric constant layer.

A patterning process for the upper metal interconnection layer 210 is generally implemented using a damascene process. A trench or second via is first formed in the first interlayer dielectric layer 209; and then the trench or second via is filled with Cu to form the pattern of the first metal interconnection layer.

In some embodiments, a second etch stop layer 208 is formed at the bottom of the first interlayer dielectric layer 209, where the material of the second etch stop layer 208 includes aluminum oxide (AlO).

Generally, a pattern of back-end-of-line interconnection metal includes patterns of a plurality of metal interconnection layers. After the pattern of the upper metal interconnection layer 210 is formed, if patterns of more metal interconnection layers are required to be formed, a subsequent process for forming a pattern of a metal interconnection layer may be continued.

In the prior art, after the via metal layer is formed, metal CMP is performed once to remove the via metal layer outside the via opening, or dielectric CMP is added to implement the metal protrusion. Unlike the prior art, in the embodiment of the present disclosure, after the first metal layer 207a is formed, the first-time metal CMP is performed to remove the first metal layer 207a on the top surface of the first dielectric layer 204 outside the via opening 205. In this case, the recess may be formed on the top surface of the first metal layer 207a at the via opening 205 due to the electrochemical reaction corrosion caused by the first-time metal CMP. On that basis, in the embodiment of the present disclosure, instead of continuing the dielectric CMP to remove the recess of the first metal layer 207a, a second-time dielectric etch back process is performed to etch back the first dielectric layer 204, so as to form the metal protrusion 2071 and thereby ensure the elimination of the recess of the first metal layer 207a. With advantages of the second-time dielectric etch back process, such as higher selectivity of the second-time dielectric etch back process for the first dielectric layer 204, better etching uniformity, and less damage to a surface film, the metal protrusion 2071 free of defects and having a specific height may be formed. In particular, the second-time dielectric etch back may be implemented using a chemical gas etching process, such as Certas etching. The Certas etching has an extremely high etching selectivity ratio for oxides and etching uniformity significantly better than that of CMP and causes no damage to a surface film, thereby optimizing the in-plane uniformity of the metal protrusion 2071, eventually ensuring that the via 207 metal layer is in good contact, i.e., full contact, with the pattern of the upper metal interconnection layer, avoiding a high resistance caused by a poor contact or an open circuit caused by contactless disconnection, also ensuring that a via 207 structure is uniform in a plane and free of scratches, thereby improving device performance and increasing a product yield.

The embodiment of the present disclosure is particularly applicable to a relatively low process node. As the process node shrinks, the size of a device decreases, the width and the height of the via 207, especially the zeroth layer via, decrease, and any defect and damage caused by the CMP during the formation of the via 207 may impose a significant impact on the performance of the device. In the embodiment of the present disclosure, a method of the first-time metal CMP plus the second-time dielectric etch back may be used to improve a structural property of the via 207 at a small process node, avoiding a high contact resistance or an open circuit and thereby improving the device performance.

The present disclosure is described in detail above through specific embodiments that, however, do not impose limitations to the present disclosure. Without departing from the principle of the present disclosure, a skilled in the art may also made many other deformations and improvements, which should also be considered as the scope of protection of the present disclosure.

What is claimed is:

1. A method for manufacturing a via, comprising:
providing an underlying structure, and forming a first dielectric layer on a surface of the underlying structure;
performing patterned etching on the first dielectric layer to form a via opening;
forming a first metal layer that fully fills the via opening and extends to a top surface of the first dielectric layer outside the via opening;
performing first-time metal chemical mechanical polishing (CMP), wherein the first-time metal CMP removes the first metal layer on the top surface of the first dielectric layer outside the via opening, and a top surface of the first metal layer in the via opening is located below the top surface of the first dielectric layer;
performing second-time dielectric etch back, wherein the second-time dielectric etch back selectively etches the first dielectric layer and lowers the top surface of the first dielectric layer as being below the top surface of the first metal layer, the via is composed of the first metal layer filling the via opening and comprises a metal protrusion formed by the first metal layer above the top surface of the first dielectric layer, the second-time dielectric etch back ensures that the metal protrusion is uniform in a plane and is free of scratch defects; and
forming a pattern of an upper metal interconnection layer, wherein the metal protrusion ensures that the via is in full contact with the pattern of the upper metal interconnection layer and avoids a high resistance and an open circuit.

2. The method for manufacturing the via according to claim 1, wherein the first dielectric layer comprises an oxide layer.

3. The method for manufacturing the via according to claim 2, wherein a process for forming the first dielectric layer comprises a PECVD deposition process.

4. The method for manufacturing the via according to claim 2, wherein, prior to the forming the first metal layer, the method further comprises:
forming an adhesion barrier layer, wherein the adhesion barrier layer is formed on an inner surface of the via opening and extends to the top surface of the first dielectric layer outside the via opening, and the first metal layer fully fills the via opening and extends to the top surface of the adhesion barrier layer outside the via opening.

5. The method for manufacturing the via according to claim 4, wherein a material of the first metal layer comprises W, and the adhesion barrier layer comprises a Ti layer and a TiN layer stacked in sequence.

6. The method for manufacturing the via according to claim 1, wherein the second-time dielectric etch back is implemented by means of a chemical gas etching process.

7. The method for manufacturing the via according to claim 6, wherein the chemical gas etching process is Certas etching.

8. The method for manufacturing the via according to claim 7, wherein the second-time dielectric etch back reduces a height of the top surface of the first dielectric layer by 5-10 nm, so that a height of the metal protrusion satisfies a requirement that the via is in full contact with the pattern of the upper metal interconnection layer.

9. The method for manufacturing the via according to claim 8, wherein an amount of height reduction of the top surface of the first dielectric layer is controlled by controlling a duration of the second-time dielectric etch back.

10. The method for manufacturing the via according to claim 1, wherein the via is a zeroth layer via, a process of forming a zeroth metal layer is completed on the underlying structure, and the pattern of the upper metal interconnection layer is a pattern of a first metal interconnection layer.

11. The method for manufacturing the via according to claim 10, wherein a material of the zeroth metal layer comprises Co.

12. The method for manufacturing the via according to claim 10, wherein a material of the first metal interconnection layer comprises Cu.
